(19) United States
(12) Patent Application Publication
(10) Pub. No.: US 2012/0007660 A1
(43) Pub. Date: Jan. 12, 2012

(54) Bias Current Generator

(76) Inventors: Derek HUMMERSTON, Hungerford (GB); Christopher Peter Hurrell, Cookham (GB)

(21) Appl. No.: 12/832,517

(22) Filed: Jul. 8, 2010

(51) Int. Cl. G11C 5/14

(52) U.S. Cl. 327/530

(57) ABSTRACT

A bias current generator comprising at least one field effect transistor operating as a current source or sink, a capacitive store for storing a first control voltage, and a first switch for selectively connecting the capacitive store to a gate of the at least one field effect transistor.

### FIELD OF THE INVENTION

The present invention relates to a bias current generator, and in particular to one operated in a discontinuous manner.

### BACKGROUND TO THE INVENTION

Many signal processing circuits employ amplifiers in order to manipulate the amplitude of signals being processed. Such amplifiers often include differential gain stages using transistors arranged in a long tail pair configuration. It is common for this configuration to be connected to a current source or to a current sink. It is also known to the person skilled in the art that many other signal processing blocks also utilise current sources or current sinks.

In many applications an amplifier or other signal processing element is used in a discontinuous manner. That is, it is only required to be on for relatively brief periods of time in order to, for example, amplify a signal such as a residue formed by an Nth stage of a pipeline analog to digital converter prior to passing the amplified residue to an (N+1)th stage of the analog to digital converter. Thus, in applications where power consumption is critical, such as battery operated devices, it is possible to reduce the overall power consumption of the device by switching the amplifier off when it is not needed.

A downside of switching amplifier blocks off is that they are not continuously available, and there is generally a delay between seeking to re-power an amplifier block and the amplifier, or indeed other circuit, having stabilised into a working configuration.

One approach for reducing power consumption within amplifiers, which is akin to switching them off, is to remove the bias currents from the long tail pair stages.

### SUMMARY OF THE INVENTION

According to a first aspect of the present invention there is provided a bias current generator comprising at least one field effect transistor operating as a current source or sink, a capacitive store for storing a first control voltage, and a first switch for selectively connecting the capacitive store to a gate of the at least one field effect transistor operating as the current source or sink.

It is thus possible to provide an arrangement in which a suitably precharged capacitive storage element may be connected to the gates of at least one field effect transistor operating as a current source or sink so as to switch that transistor from a non-conductive state to a current controlling state. This approach is particularly suited for use with current sources or current sinks which are operated in a discontinuous manner because the gate voltage stored by the capacitive store can be maintained on the transistor long enough for the signal processing stage receiving current from the current source or sinking current to the current sink in order to perform its signal processing job.

Preferably the current source or sink can be turned off by disconnecting the capacitive store from the at least one field effect transistor and/or using a shorting transistor to return the gate-source voltage of the at least one field effect transistor forming the current source or current sink to a non-conducting state.

In some embodiments of the present invention the current sources or current sinks may be in series connection with another transistor, such as a cascode transistor, whose control voltage can be modulated in order to act as a switching device thereby inhibiting current flow from the current source to the current sink irrespective of whether the current source or current sink is notionally “on”.

Advantageously a precharge circuit is provided for precharging the capacitive store when the capacitive store is not connected to the at least one field effect transistor forming the current source or the current sink. The precharge circuit may, in one embodiment, comprise connecting the capacitive store between the power supply rails of a circuit or connecting the capacitive store to a voltage source so as to charge the capacitor. However, in a preferred implementation the capacitive store is connected to an output of a current to voltage converter. The current to voltage converter is advantageously the reference limb of a current mirror. The reference limb of the current mirror may be formed by connecting a field effect transistor in a diode connected configuration. Thus, for example, the drain and the gate of a field effect transistor can be connected together such that the gate voltage and the drain voltage are the same, and the gate voltage floats to whatever value is required in order to pass a reference current, which is supplied to the transistor in the reference limb of the current mirror. This gate voltage can then be supplied to the at least one field effect transistor operating as a current source or current sink and as the transistors are matched that transistor will pass the same current, subject to any scaling factor as a result of changes in devices size. The use of this current mirror approach is advantageous because use of matched transistors means that process variations or thermal effects affect the reference transistor and the current source/current sink transistor substantially equally such that the currents therein continue to match each other.

In a further embodiment of the present invention the reference transistor has its gate electrode connected in a potential divider formed between its source and drain electrodes such that the voltage at the drain of the reference transistor is a multiple of the gate source voltage of the transistor in the reference limb of the current mirror. The drain voltage then acts as the first control voltage which is stored on the capacitive store. The capacitive store is sized with knowledge of a “load” capacitance formed by the at least one field effect transistor operating as the current source or current sink such that when the capacitive store is connected to the at least one field effect transistor operating as the current source or current sink the load capacitance and the capacitance of the capacitive store engage in charge sharing such that the voltage provided at the gate of the at least one field effect transistor operating as the current source or current sink matches the gate voltage of the reference transistor.

Advantageously a buffer amplifier is provided at the output of the current to voltage converter in order to buffer the voltage output of the current to voltage converter. As a result the amount of current required by the current to voltage converter can be reduced, and the buffer amplifier can take care of the task of driving the capacitive load presented by the gates of the at least one field effect transistor acting as the current source or current sink.

Advantageously the buffer has an output stage comprising two output transistors operated in a totem pole or “push-pull” configuration such that the output stage of the buffer need not take any significant amounts of current when it has reached its desired output voltage.

In a variation of the invention, the buffer amplifier may be in the form of a flipped voltage follower. In such a configuration two transistors are still provided in a ‘totem-pole’ like configuration, but the transistors are of the same type. Furthermore, rather than having both their gates connected to the input signal, one of the gates is directly connected to the input, and the other is connected to a node between a further transistor and a current sink or current source.

Advantageously the capacitive store is formed as a capacitor within an integrated circuit. More advantageously the capacitive store is formed by the gates of one or more field effect transistors such that the capacitive store and the load capacitor formed by the at least one field effect transistor operating as the current source or current sink scale together with processing variations and are equally affected by device temperature effects. The capacitive store may itself be formed by transistors operating as current sources or current sinks.

According to a second aspect of the present invention there is provided a bias generator comprising a current mirror comprising a first limb for generating a voltage reference as a result of a current flowing in the first limb, and at least one second limb for passing a current as a function of the reference voltage, wherein a buffer is provided between the first and second limbs.

### BRIEF DESCRIPTION OF THE DRAWINGS

The present invention will further be described, by way of non limiting example only, with reference to the accompanying Figures, in which:

FIG. 1 schematically illustrates a bias current generator for distributing a plurality of bias currents;

FIG. 2a illustrates the evolution of bias current from a bias reference generation circuit as a function of time following application of a “power-up” signal, and

FIG. 2b illustrates the evolution of a control voltage as a function of time supplied to the gates of the field effect transistors operating as current sinks in FIG. 1;

FIG. 3a represents the evolution of a plurality of reference currents from the reference current generator, and

FIG. 3b schematically illustrates the evolution with time of the control voltage for each of the reference currents;

FIG. 4 schematically illustrates a bias current generator having a buffer amplifier constituting a first embodiment of the present invention;

FIG. 5 shows the circuit of FIG. 4 in greater detail, and includes a representation of the internal circuit of the buffer amplifier;

FIG. 6 shows a circuit constituting a second embodiment of the present invention and having a capacitive store connectable to the at least one field effect transistor forming the current source or current sink so as to improve its response time, together with a reference voltage generator and a buffer amplifier;

FIG. 7 shows the evolution of the output current as a function of time for the circuit illustrated in FIG. 6;

FIG. 8 shows a circuit configuration of a bias current generator constituting a further embodiment of the present invention;

FIG. 9 shows a modification to the circuit of FIG. 8 where the storage capacitive element therein is formed by the gates of field effect transistors;

FIG. 10 shows the evolution of the gate voltage with respect to time at a transistor acting as a current sink following initiation of a power-up signal at time t=0;

FIG. 11 schematically illustrates a further embodiment of the present invention where the capacitive store for storing the first control voltage is formed by the gate capacitances of a first group of current control transistors, and the load capacitance is formed by a second group of current control transistors; and

FIG. 12 shows a modified buffer amplifier design.

### DESCRIPTION OF PREFERRED EMBODIMENTS OF THE INVENTION

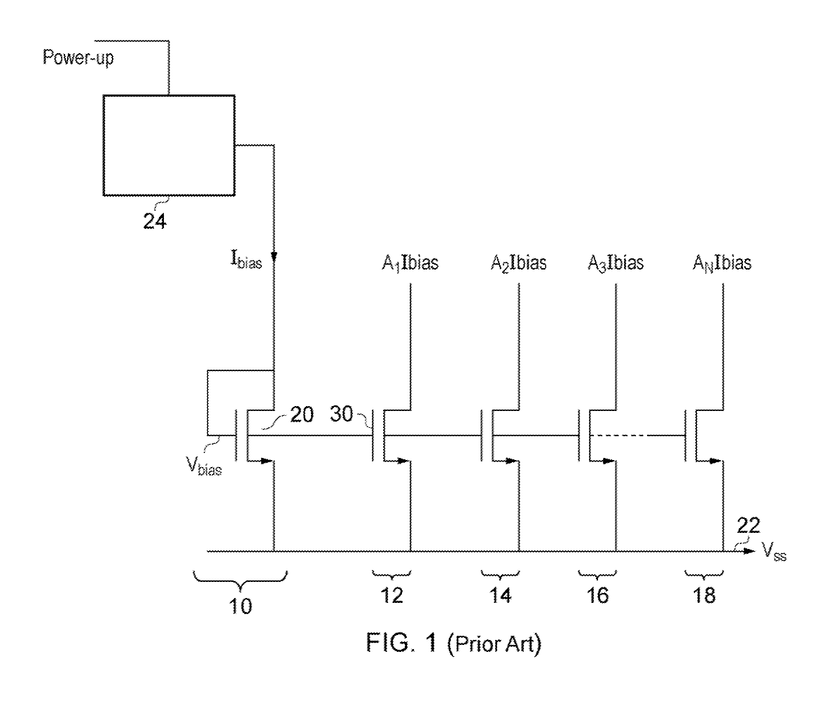

FIG. 1 schematically illustrates a prior art bias current generation and distribution circuit for use within an integrated circuit. The circuit comprises a current mirror which, for simplicity, can be regarded as having a first limb which functions as a reference limb 10 and a plurality of second or distribution limbs 12, 14, 16 and 18. A bias current I_{bias} is provided to a reference transistor 20 in the reference limb 10. The reference transistor 20 is a field effect transistor having its gate connected to its drain and its source connected to a low voltage power rail 22 which, in the case of battery operated equipment is designated Vₛₛ. The bias current I_{bias} may be provided by a controllable reference current generation circuit 24 whose internal construction is not relevant to the present invention. However for completeness the reference current generation circuit 24 may include, for example, a series connected resistor and transistor switch such that when the transistor switch is conducting the resistor effectively extends between a positive voltage, such as the positive supply rail V_{dd} (not shown) and the drain of the reference transistor 20. In more complex circuits the circuit 24 may include a voltage reference such that the reference bias current is substantially immune from changes in the supply voltage thereto.

In use the reference transistor 20 passes the reference bias current from its drain terminal to its source terminal and, because it is in diode connected configuration the gate-source voltage rises to whatever value is necessary in order to cause the transistor to conduct the reference bias current. Thus the gate voltage forms a control voltage. This control voltage is then passed to the gate of a field effect transistor in a second limb 12 of a current mirror. The second limb comprises a transistor 30, which can be regarded as a slave transistor, which is matched to the transistor 20 and hence the second limb will wish to pass a bias current A₁I_{bias} which is related to the reference bias current. If the transistors 20 and 30 are identical in size then A₁I_{bias} will be equal to the reference bias current but typically the transistor 30 is bigger (wider) and the current passing there through scales with the relative size of the transistor 30 with respect to the reference transistor 20. The second limb 12 of the current mirror can be regarded as a slave limb with the first limb 10 acting as a master. Because field effect transistors present an extremely high gate impedance multiple slave limbs or second limbs 14, 16, 18 and so on can be driven from the same reference transistor 20. The transistors in the further slave limbs or second limbs can have different sizes such that each can be tailored to pass an individual bias current A₂I_{bias}, A₃I_{bias} . . . A_{N}I_{bias}, with all the respective currents being scaled and related to one another by the relative device sizes. The bias currents from the slave limbs 12, 14, 16 and 18 may be provided to amplifier or other signal processing stages, and those stages may only need to be activated for relatively short periods of time. It is therefore advantageous, from the power consumption point of view, to switch those stages off in order to conserve current when they are not actually needed. This can be achieved in the arrangement shown in FIG. 1 by removing the power-up signal from the reference current generation circuit 24 such that the reference bias current ceases to flow and consequently each of the slave limbs 12, 14, 16 and 18 ceases to pass a current.

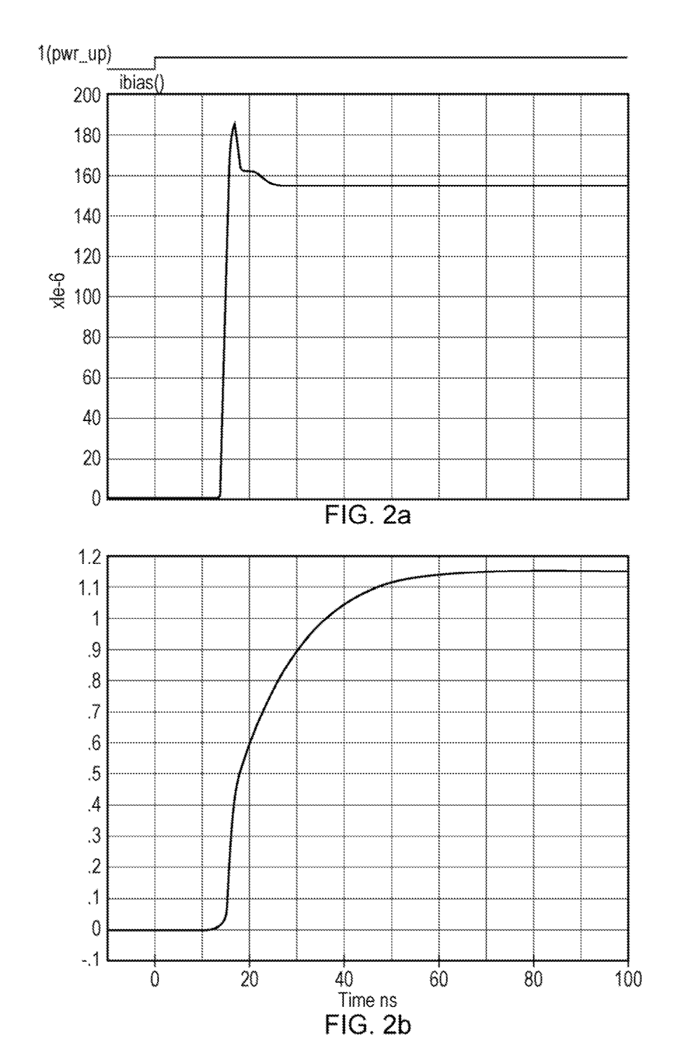

FIG. 2a schematically illustrates the evolution of the reference bias current as a function of time following application of the power-up signal, and FIG. 2b schematically illustrates the evolution of the control voltage. FIGS. 2a and 2b share the same time axis, which is shown along the horizontal of FIG. 2b. The time axis represents time in nanoseconds. It can be seen that at an arbitrary time, represented as “zero” the power-up signal power-up is asserted. It takes approximately 15 nanoseconds for the reference bias current to be provided by the circuit 24 to the transistor 20. The reference current then rises rapidly and has become substantially settled by 25 nanoseconds after application of the power-up signal. Meanwhile it can be seen from FIG. 2b that the control voltage starts to rise after about 15 nanoseconds from assertion of the power-up signal but follows an exponential rise and doesn't become useable until about 70 nanoseconds after power-up was asserted. The reason for this is that to minimise noise the transistors in the slave limbs of the current mirrors are often made physically large and therefore present a sizable capacitance which has to be charged using the reference bias current. For transistors having, for example, dimensions of 32×2.5 microns, each device presents a capacitance of approximately 0.6 pico-farads between its gate and source terminals when fully biased. All of these load capacitances sum together to form a distributed capacitance C_{load} which must be charged by the incoming reference bias current before the slave transistors of the current mirror start to conduct.

The diode connected reference transistor acts as a trans-conductor which converts the incoming reference bias current into the control voltage and generally the incoming reference bias current is small compared to the mirrored currents. Typically the scaling factor is 5:1 or greater and hence in the example shown in FIG. 1 the current flowing through the reference transistor 20 is typically 150 μA or less. Because the reference transistor acts as a transconductance it has an effective impedance. In the example shown in FIGS. 2a and 2b the transconductance of the transistor 20 was 0.4 mS giving an equivalent resistance of 2.5 kΩ, and the capacitive load presented by the sum-total of the slave transistors was 3.0 pico-farads, giving a time constant of 8.3 nanoseconds.

For applications, such as amplifiers, once the bias currents have settled, which is noted before in this example takes around 70 nanoseconds, other parts of the amplifier circuit, such as common mode loops and feed back loops need to settle, and capacitances to charge, such that the wake up time for the amplifier incorporating the current mirrors might be in the order of 100 nanoseconds. This, in applications such as analog to digital converters represents quite a long settling time.

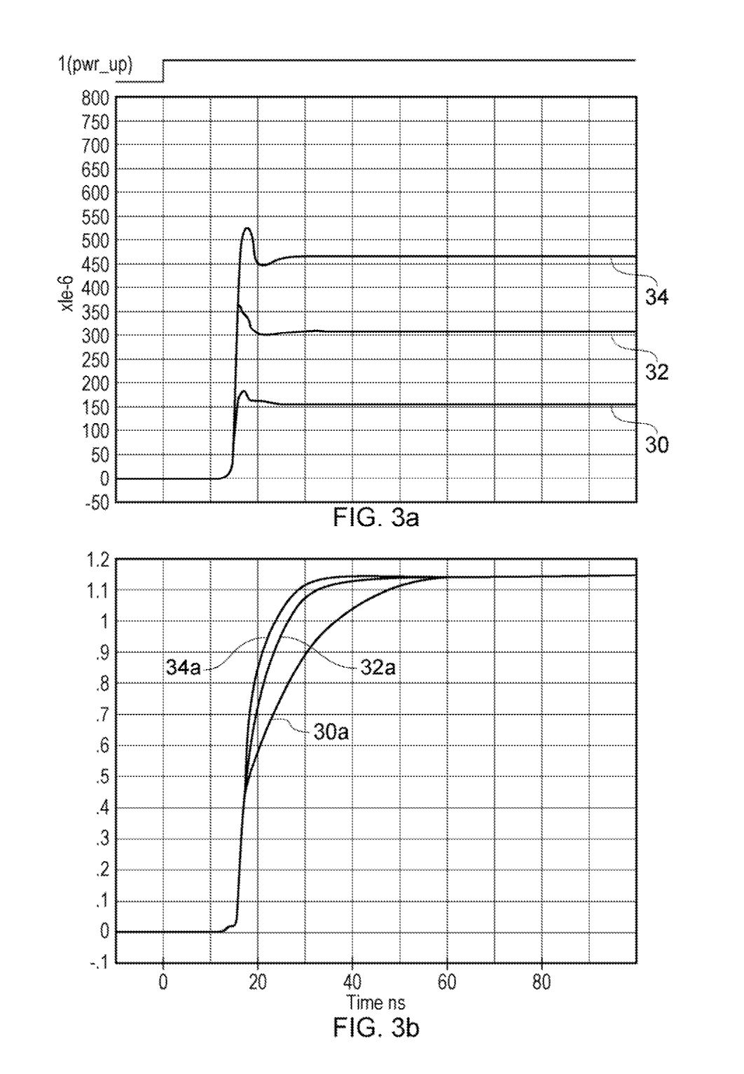

It is known from the prior art that the wakeup time can be improved by burning more current in the reference limb of the current mirror. At the same time the transconductance of the diode connected reference transistor is increased by increasing its aspect ratio in order to keep the desired V_{GS} the same. FIG. 3a shows three plots of bias current where the plot designated by line 30 represents a reference current of one arbitrary unit, which in this example is 150 μA as was the case for the discussion of FIG. 2, line 32 represents a reference current of 2× the arbitrary reference current, and line 34 represents a reference current of 3× the arbitrary reference current. The resulting evolution of the control voltage as a function of time is shown in FIG. 3b and designated 30a, 32a and 34a respectively.

FIG. 3b shows that when I_{bias} is doubled and the width of the reference transistor 20 is increased by the same factor, then the settling time of the current mirror has been reduced, and the current mirror is now settled by 55 nanoseconds after the power-up signal was asserted. Further increasing the bias current reduces the settling time, but not by much such that, in reality, only a 20 nanosecond improvement in switch on time is obtained even when the reference bias current is significantly increased. Furthermore there is still a 15 nanosecond dead time whilst the current mirror waits for the reference bias current to become established from the external bias current generator 24.

Referring to FIGS. 2 and 3, it can be seen that the large time constant of the current mirror is a significant limitation on the wakeup time that can be achieved. Increasing the transconductance of the diode connected reference transistor 20 does, as shown in FIG. 3b helps the problem, but comes at the cost of extra power.

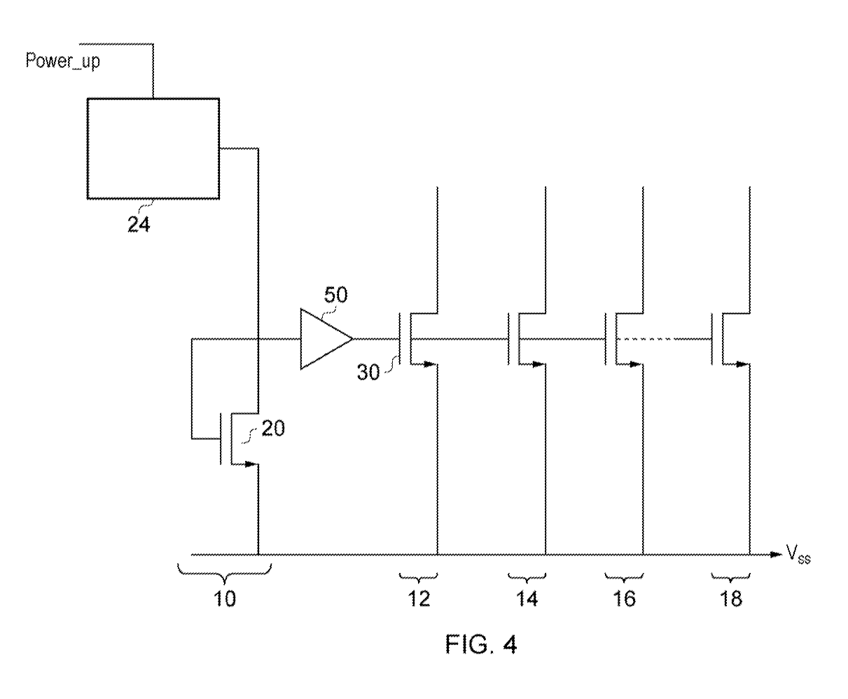

The inventor realised that one way to overcome the time constant of the current mirror would be to insert a buffer 50, as shown in FIG. 4, in the signal path between the reference transistor 20 and the slave transistors 30 of the second limbs 12, 14, 16 and 18 of the current mirror. The buffer breaks the connection between the large load capacitance C_{load} presented by the gates of the slave transistors and the diode connected reference transistor. Admittedly the bias transistor still presents its own gate capacitance to the reference bias current, but this is relatively small and hence the reference transistor can be arranged to have a time constant in the order of 1 nanosecond or so. A second time constant consists of the RC circuit formed by the combined gate capacitances C_{load} of the slave transistors 30 in the second limbs of the current mirrors and the effective impedance Rₒᵤₜ of the buffer 50. However it is relatively straight forward to make the buffer output impedance significantly less than the output impedance

$$( \frac{1}{gm} )$$

of the reference transistor 20.

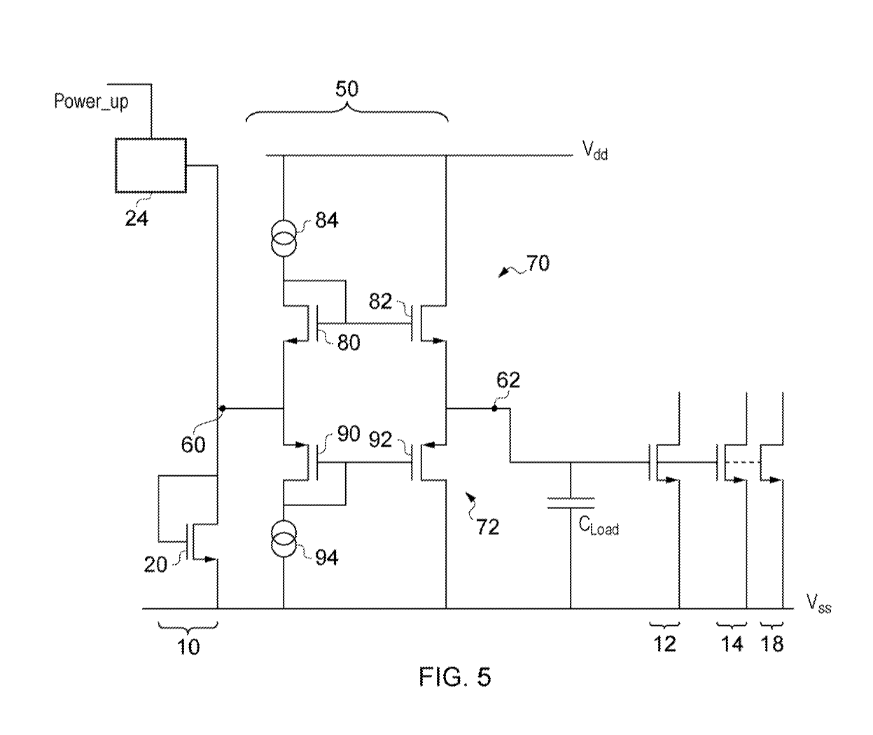

FIG. 5 schematically illustrates the arrangement of FIG. 4 in greater detail, and in particular shows the internal configuration of an exemplary embodiment of the buffer 50. Furthermore, the parasitic gate capacitances of the slave transistors in the second limbs 12, 14 and 18 have been identified as a load capacitor C_{load} in order to make this capacitance explicit.

The buffer amplifier has an input node 60 connected to the drain of the reference transistor 20 and an output node 62 connected to the gates of the slave transistors in the second limbs 12, 14 and 18 of the current mirror. The buffer 50 comprises a pull-up arrangement, generally designated 70 and a pull-down arrangement, generally designated 72. In this example, both the pull-up arrangement 70 and the pull-down arrangement 72 are active, in that they are implemented by transistors, but it would be possible for one of them to be omitted and a passive, for example, resistive, pull-up or pull-down element to be included to co-operate with the active pull-down or pull-up element, respectively.

The pull-up circuit 70 comprises a first pull-up transistor 80 and a second pull-up transistor 82. A current control element 84 is also provided, which could be a current mirror as shown here or merely a resistor. A drain of the first pull-up transistor 80 is connected to receive current from the current control element 84, and a source of the first pull-up transistor 80 is connected to the input node 60. The gate of the first pull-up transistor 80 is connected to its drain. Consequently it can be seen that provided the current passing through the first pull-up transistor 80 can be sunk somewhere, either by passing through the pull-down circuit 72 or by passing through the reference transistor 20, then the gate voltage of the first pull-up transistor 80 tracks the drain voltage of the reference transistor 20 subject to an offset. The second pull-up transistor has its gate connected to the gate of the first pull-up transistor, its drain connected to a positive supply rail V_{DD} and its source connected to the output node 62. Thus the second pull-up transistor 82 is configured as a source follower and its source voltage tracks its gate voltage subject to an offset V_{GS}. Transistors 80 and 82 are fabricated as matched devices so it follows that the voltage at the source of the second pull-up transistor 82 is the same as the voltage at the source of the first pull-up transistor 80, and consequently the voltage at the output node 62 is the same at the voltage at the input node 60, subject to any slight transistor mismatches that may have occurred during fabrication.

Because the transistors 82 can only pull-up, then a pull-down load should also be provided at the output node 62, but this could merely be a resistor between the node 62 and the supply rail Vₛₛ. However, in the preferred embodiment the pull-down circuit 72 is provided, which comprises a first pull-down transistor 90, a second pull-down transistor 92 and a current control device 94. The current control device 94 is preferably a current mirror arranged to pass substantially the same current as the current mirror 84 such that the buffer circuit neither injects nor draws current from the connection to the reference transistor 20. The source of the first pull-down transistor 90 is connected to the input node 60, its drain is connected to the current sink 94 and its gate is connected to its drain. The second pull-down transistor 92 has its gate connected to the gate of the first pull-down transistor 90, its source connected to the output node 62 and its drain connected to V_{SS}. Thus the operation of the pull-down circuit is substantially the same of the operation of the pull-up circuit. The transistors 82 and 92 co-operate to form a push-pull output stage and consequently can sink or source current from or to the capacitive load C_{load} in order to charge it quickly to the correct voltage, but do not pass significant amounts of current once the output node has achieved the correct voltage. Thus the buffer amplifier can speed up the charging of the gate electrodes of the slave transistors to their correct voltage without incurring a significant current penalty. The current mirrors 84 and 94 are preferably arranged to pass a fraction, for example ⅓, of the reference current.

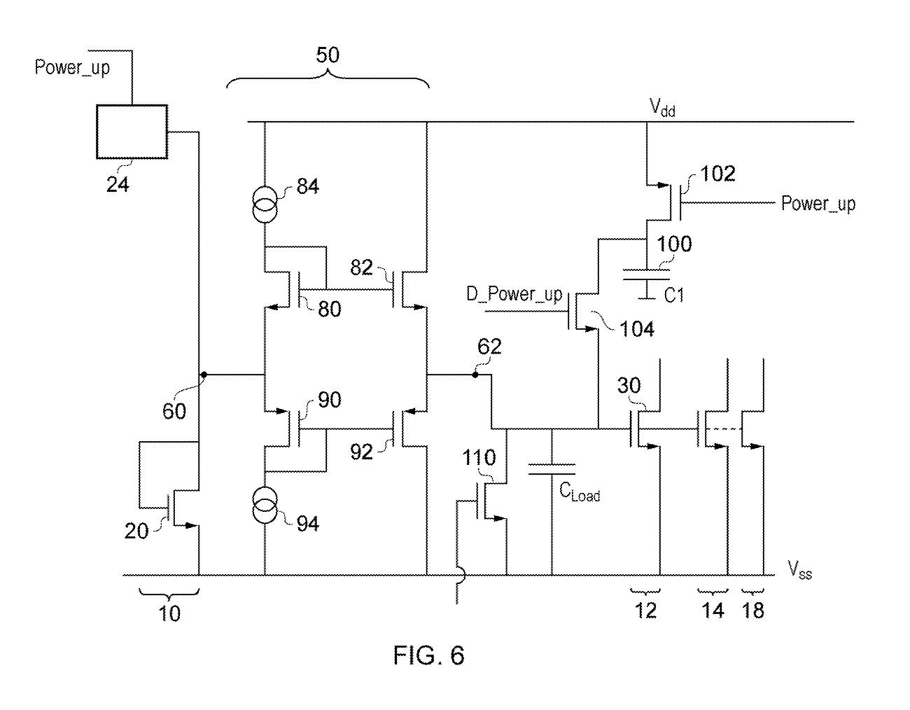

FIG. 6 illustrates a circuit similar to that of FIG. 5, but including a capacitive store 100 for storing a first control voltage which is precharged and can be used to “kick start” operation of the slave limbs 12, 14 and 18 of the current mirrors. Capacitive store 100 is associated with a charging transistor 102 which acts as a switch to selectively connect or disconnect, the capacitive store 100 to the supply rail V_{dd}. In operation, V_{dd} remains continually powered such that when the power-up signal is removed from the bias reference generator 24 the switch 102 is closed. This allows the capacitive store 100 to become charged to the supply voltage V_{dd}. It can be seen that if power-up is active when high, and switch 102 is implemented as a high side PMOS switch, then power-up can be used to control the reference circuit 24 and the switch 102 because power-up going high causes transistor 102 to become non-conducting, whereas power-up going low causes transistor 102 to become conducting. It can therefore be seen that, just before assertion of the power-up signal the capacitive store 100 is charged. At assertion of the power-up signal the reference current generator starts initialising and simultaneously switch 102 goes high impedance. Shortly after assertion of the power-up signal a delayed signal “D_power-up” is provided to the gate of a transistor 104 acting as an electrically controlled switch interconnecting the capacitive store 100 and the gates of the slave transistors in the second limbs of the current mirrors. If D_power-up goes high just a few nanoseconds after power-up was asserted, then the capacitive store 100 is connected to the slave transistors, and the capacitive store 100 interacts with the parasitic load C_{load} to form a capacitive potential divider by virtue of charge transfer between the capacitive store 100 and the parasitic load C_{load}. It can be seen that by selecting the ratios of the capacitive store 100 and C_{load} correctly, that the voltage on the gates of the slave transistors can very quickly be placed at around the correct voltage corresponding to that at the output of the reference limb 10 once the current mirror operation has become established. This precharging arrangement can be used with or without the buffer amplifier 50. The relative sizes of the capacitive store 100 and the parasitic load C_{load} need to be taken into consideration by the circuit designer, as does the desired operating voltages. However if, for example, V_{dd} was 1.8 volts, and the nominal voltage at the output of the reference limb 10 was 1.2 volts, then it can be seen that if the capacitance C₁ of the capacitive store 100 was twice that of the parasitic capacitance C_{load}, then charge distribution between these capacitors would result in the gate voltages rising to 1.2 volts almost immediately after transistor 104 had been made conducting. In use the delayed power-up signal D_power-up used to control switch 104 is only asserted for a few nanoseconds before being removed again. This prevents the load C₁ of the capacitive store 100 being presented to the transistor 20 if the buffer amplifier 50 is omitted, or to the buffer amplifier 50 when the buffer amplifier is provided.

A further transistor 110 is provided as a second switch to discharge the parasitic load capacitance C_{load} when the power-up signal is removed.

It is thus possible to provide enhanced turn on and turn off speeds for the second or slave limbs of the current mirror.

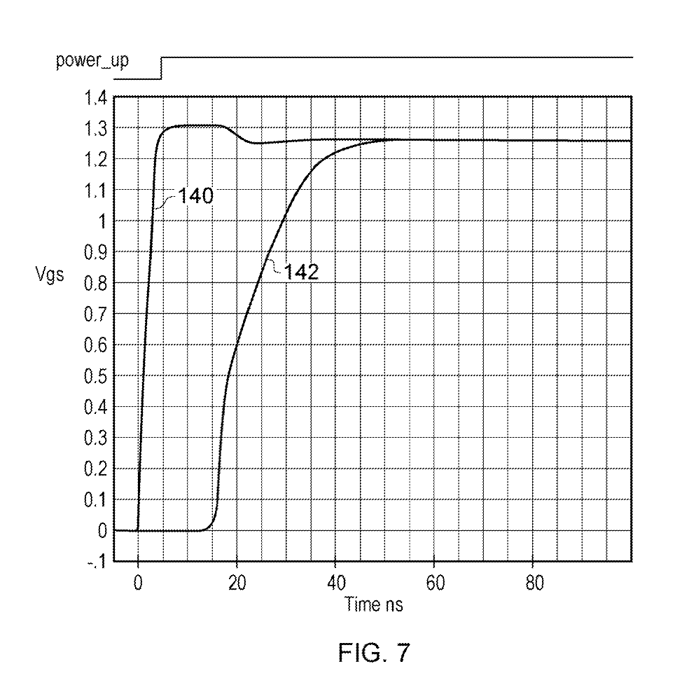

FIG. 7 is a plot showing the relative performance of the circuit shown in FIG. 6 having the additional kick-start circuitry compared to the circuit shown in FIG. 5 where the kick-start circuit is not provided. The line 140 represents the voltage at the gates of the slave transistors, and it can be seen that the transistors have turned on within the first 10 nanoseconds, and that the bias currents have settled to their steady state about 25 nanoseconds before the equivalent circuit, shown in FIG. 5, but without the kick-start arrangement.

It can also be seen that although the current mirrors start to conduct almost immediately there is a little overshoot which must be corrected by the buffer before the mirrors can be regarded as settled to a reasonable accuracy. The absolute value of the bias voltage V_{bias} changes with temperature and process, but not supply voltage, whereas the charge transferred to the capacitive store 100 depends only on the voltage supply. As a result there will always be a small error for the buffer amplifier to correct.

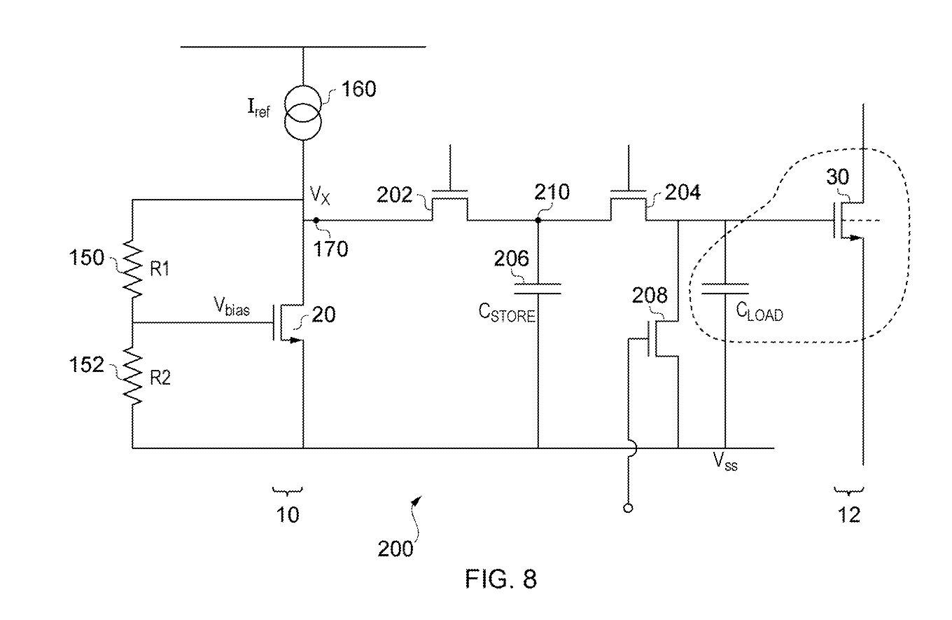

FIG. 8 shows a further embodiment of the present invention in which the precharge/kick-start circuit has been modified such that it can accurately charge the parasitic gate capacitance C_{load} to the correct gate source voltage for the desired current. As shown in FIG. 8 the reference arm of the current mirror is modified by the inclusion of a potential divider comprising resistors 150 and 152. Resistor 150 is connected between the drain and the gate of the reference field effect transistor 20 and resistor 152 is connected between the gate and the source of the reference field effect transistor 20. The reference transistor is, as before, provided with a reference current which is shown as being supplied by a current source 160. It is a matter of design choice whether the current source 160 is on permanently or whether it can be switched on and off, as per current reference 24 as in FIG. 1. As before, the gate of the transistor 20 achieves a voltage, designed V_{bias}, such that the transistor passes the reference current. We also know that if the voltage at the drain of the transistor 20 is represented as V_{X} then the potential divider action of the resistors 150 and 152 relates V_{X} to V_{bias} such that

$${V}_{X} = {V}_{bias} \times ( \frac{{R}_{1} + {R}_{2}}{{R}_{2}} )$$

thus the reference limb of the current mirror has been slightly modified such that its output voltage V_{X}, is no longer the gate source voltage of the reference transistor 20 but a multiple of it. The or each slave limb of the current mirror 12 is arranged to receive this voltage V_{X} via an intermediate change transfer circuit. Furthermore, the capacitive load of each of the slave transistors of the slave or second limbs of the current mirror is represented by a composite capacitance C_{load}. It should be bourn in mind that C_{load} is not fabricated as an actual component but merely the sum of the gate capacitances. An intervening charge transfer circuit, generally designated 200 comprises first and second series connected switches implemented as field effect transistors 202 and 204 which extend between an output node 170 of the reference limb of the current mirror 10 and the gates of the slave transistors in the second limbs of the current mirror. A capacitive store, designated 206 having capacitance Cₛₜₒᵣₑ extends between a node 210 formed between the first and second switches 202 and 204 and the supply rail Vₛₛ. A shorting switch implemented as a transistor 208 is provided in parallel with the parasitic capacitive load C_{load}, and consequently can be operated to connect the gates of the field effect transistors acting as the current source or current sink to ground or Vₛₛ. In this example the transistors act as current sinks, but it is evident that an equivalent circuit can be fabricated using PMOS devices and connected to V_{dd}.

In operation switch 202 can be closed and switch 204 opened such that the capacitor 206 is connected to reference limb 10 and hence charged to voltage Vₓ. This occurs during a precharge stage when the slave current mirrors 12 are not required to provide any current. When it is desired to switch the slave current mirrors on transistor 202 is made non-conductive and transistor 204 is made conducting such that the capacitor 206 is connected to the gates of the slave transistors 12 and hence the capacitance Cₛₜₒᵣₑ shares its charge with the parasitic capacitance C_{load}, thereby forming a potential divider. It can be seen that if the scaling of the voltage V_{X} with respect to V_{bias} by a potential divider formed by resistors 150 and 152 is matched to the potential divider formed by the parasitic load C_{load} and the capacitive store 206 then the circuit can transfer the correct voltage V_{bias} from the gate of the reference transistor 20 to the gates of the slave transistors 30 via the intervening transfer circuit 200. In particular, we can see that during a precharge phase

$${Q}_{store} = {C}_{store} \cdot {V}_{bias} \cdot ( 1 + \frac{{R}_{1}}{{R}_{2}} )$$

and, because transistor 208 is briefly made conducting the charge stored on the parasitic capacitor C_{load}=0. Once capacitor 206 has been charged, transistor 202 is made non-conducting and the circuit now waits for a power-up command to be given. Upon receipt of the power-up command transistor 204 is made conducting causing charge transfer to occur. The voltage at the gates of the slave transistors can be represented by V_{y}, and we can see that

$${V}_{y} \cdot {C}_{store} + Vy \cdot {C}_{load} = {C}_{store} \cdot {V}_{bias} \cdot ( 1 + \frac{{R}_{1}}{{R}_{2}} )$$

it then follows that V_{y}=V_{bias} if

$$\frac{{C}_{store}}{{C}_{store} + {C}_{load}} \cdot ( 1 + \frac{{R}_{1}}{{R}_{2}} ) = 1$$

because charge transfer from the capacitors is very rapid, it now becomes possible to switch the current mirrors on in only a few nanoseconds following the assertion of the power-up signal. The field effect transistors do not draw current from their gate when conducting, and consequently the transferred voltage is held at the gates of the slave transistors, subject only to small changes due to leakage. However, as noted because the current mirrors are operated in a discontinuous manner the current remains steady for the period over which the current mirror is required to provide a bias current to its respective circuit. After the end of the current provision period, which is typically only in the order of a few hundred nanoseconds, transistor 204 is made non-conducting, and transistor 208 is briefly switched on in order to discharge the capacitance C_{load} and therefore return the gates back to a low voltage switching the current mirrors off. The circuit can then commence a new cycle of operation with transistor 202 being switched on in order to recharge the storage capacitor Cₛₜₒᵣₑ from its diminished potential back to Vₓ.

As a further improvement Cₛₜₒᵣₑ is made out of the gate capacitances NMOS field effect transistors having identical aspect ratios to those which constitute the capacitance C_{load}. This ensures that the capacitances behave in similar ways with respect to process variations.

Making the storage capacitance 206 out of MOS devices modifies the preceding design equations because a MOS device resembles a capacitor only when its channel is formed i.e. when the gate to channel voltage is greater than the device's threshold voltage V_{T}. As a result the equations become modified such that

$${C}_{store} \cdot ( {V}_{y} - {V}_{T} ) + {C}_{load} \cdot ( Vy - {V}_{T} ) = {C}_{store} \cdot [ {V}_{bias} ( 1 + \frac{{R}_{1}}{{R}_{2}} ) - {V}_{T} ] ⇒ \\ {V}_{y} - {V}_{T} = \frac{{C}_{store}}{{C}_{store} + {C}_{load}} \cdot [ {V}_{bias} ( 1 + \frac{{R}_{1}}{{R}_{2}} ) - {V}_{T} ]$$

We want V_{y}=V_{bias}, so

$$⇒ {V}_{bias} - {V}_{T} = \frac{{C}_{store}}{{C}_{store} + {C}_{load}} \cdot [ {V}_{bias} ( 1 + \frac{{R}_{1}}{{R}_{2}} ) - {V}_{T} ] \\ ⇒ \frac{{C}_{store}}{{C}_{store} + {C}_{load}} = \frac{{V}_{bias} - {V}_{T}}{( 1 + \frac{{R}_{1}}{{R}_{2}} ) \cdot {V}_{bias} - {V}_{T}}$$

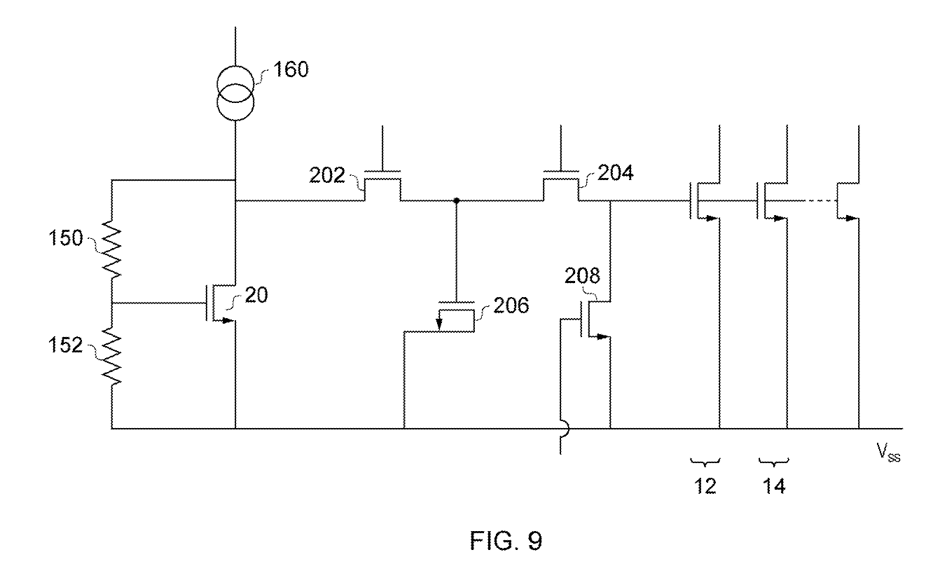

The final expression can be used to fix the ratio of the capacitors and the resistors such that at the power-up the value of V_{y} instantaneously adopts the value of V_{bias}. For a simple worked example where V_{T}=0.4 volts the bias=1.1 volts, R₂=3R1 and C_{load}=13 unit MOS devices we see that Cₛₜₒᵣₑ should be made up of 26 unit devices for V_{y} to match V_{bias} soon after power-up. FIG. 9 schematically shows, for the sake of completeness, FIG. 8 redrawn such that the capacitor 206 is formed by field effect transistors.

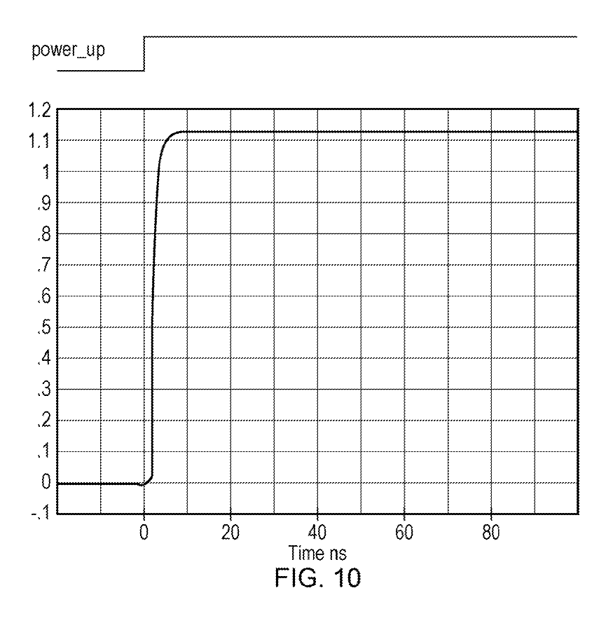

FIG. 10 illustrates the evolution of the bias voltage V_{y} as a function of time following the assertion of the power-up signal at time T=0, and it can be seen that the circuit is settled into its on state after less than 5 nanoseconds.

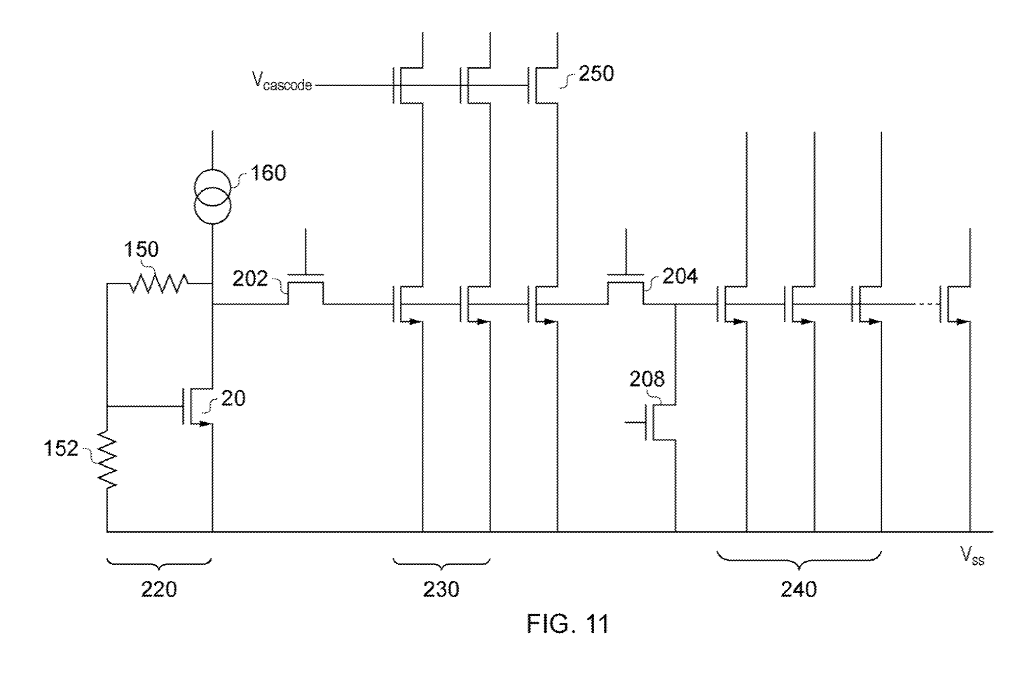

FIG. 11 shows a further variation of the arrangement of FIG. 9. Here the current mirror is provided as a reference limb designated 220 which is as described hereinbefore with respect to FIG. 8 or FIG. 9 and two groups of slave limbs with transistors of the first group 230 having their gates connected to the conductor extending between the transistor switches 202 and 204 and the second group, designated 240 being connected to the other side of the transistor 204, as was the case in the arrangement shown in FIGS. 8 and 9. It can now be seen that the parasitic capacitors of the gates of the transistors of the first group forms the precharge capacitor Cₛₜₒᵣₑ whereas the parasitic capacitance of the gates of the transistors of the second group forms the capacitance C_{load}. Thus, no additional transistors need to be formed to create the entirety of the Cₛₜₒᵣₑ capacitance and/or only one or two additional transistors need to be formed in order to balance the capacitances if such balance has not correctly been achieved by varying the values of the resistors 150 and 152 in the potential divider.

It will be appreciated that, during the precharge period the gates of transistors in the first group 230 are taken to a higher voltage than required for their correct action in the current source mode, but current flow through these transistors can be inhibited if, for example, the circuit that they drive can be switched off. This is often the case because cascode transistors, generally designated 250 are often provided in series with the current sink transistors in order to hold the voltage at their drains substantially constant.

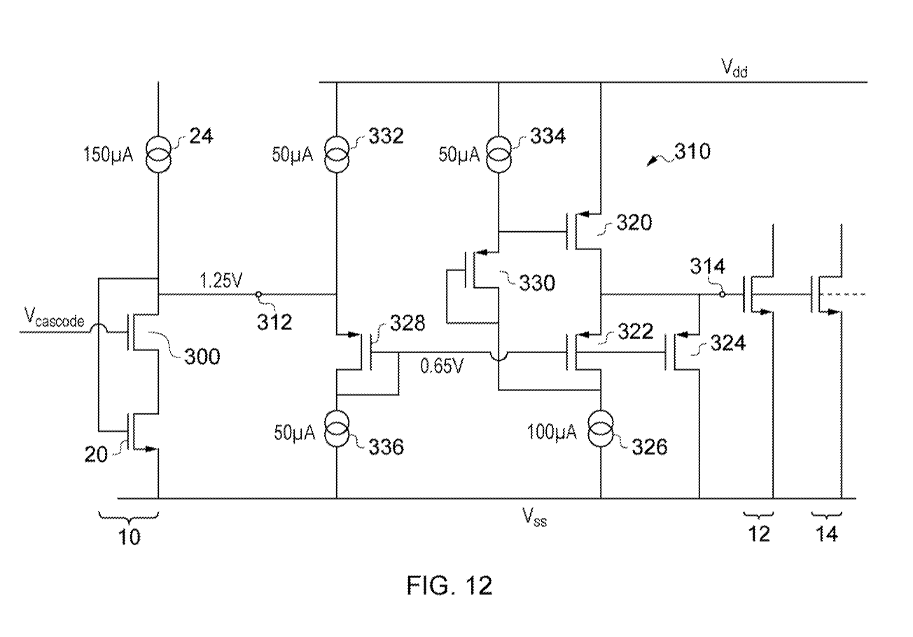

FIG. 12 shows a further variation, which can be regarded as a modification of FIG. 5. The reference limb 10 of the current mirror is provided, as before, but has been modified by the inclusion of a cascode transistor 300 with the gate connection of the transistor 10 being made intermediate the cascode transistor and the reference current source 24, which for simplicity has been shown as a current source. As a result the voltage at an output mode of the reference limb of the current mirror is typically around 1.25 volts or so. The amplifier, generally designated 310 has an input node 312 and an output node 314. The “core” working components of the amplifier 310 are the PMOS transistors 320, 322 and 324, in conjunction with the current sink 326. Additional transistors 328 and 330 in association with the current sources 332 and 334 and the current sink of 336 improve performance of the amplifier but, as will be discussed later, these components can be omitted. The output node 314 of the amplifier drives slave limbs of the current mirror 12, 14 and so on as previously discussed.

The transistors 320, 322 and 324 form a voltage follower. The gates of transistors 322 and 324 are connected together and could be connected to the input node 312, but in this example are connected to a level shifting circuit formed by the transistor 328 and the current source 322 and the current sink 326. The transistor 328 is a PMOS device with its gate connected to its drain and its source connected to the input node 312. The current source 332 and current sink 336 are set to pass nominally the same current, which in this example is 50 microamps. The voltage at the gate of the field effect transistor 328 tracks a voltage at its source, but is reduced by the value of the gate source voltage, so is typically at around 0.65 volts.

The transistor 322 has its source connected to the drain of transistor 320, to the source of transistor 324 and to the output node 314. The drain transistor 322 is connected to a current sink 326. The source of the transistor 320 is connected to the positive supply rail V_{dd} and its gate could be connected to the drain of the transistor 322, but in a preferred implementation is connected to a node between the current source 344 and the source of transistor 330 whose gate is connected to its drain and whose drain is connected to the drain of the transistor 322. Finally the drain of transistor 324 is connected to the supply rail Vₛₛ.

It is worthwhile considering the operation of the circuit. Initially, at time=zero, the reference limb 10 is switched off, and consequently its output is zero volts. The input and output nodes 312 and 314 are also at 0 volts. Transistor 328 tries to reflect this as best as it can, subject to a voltage change, and hence the voltage at its gate is also zero volts. In the start-up condition transistor 322 is off and hence the voltage at the interface between the drain of the transistor 322 and the current sink 326 is low, leading to transistor 330 conducting, and consequently transistor 320 being turned on. This allows the voltage of the output node 314 to rise rapidly to charge the parasitic capacitances of the slave limbs of the current mirror. At some point the output voltage at the node 314 becomes sufficiently high to turn transistor 322 on and it starts conducting such that a quiescent point is reached where every transistor is in saturation and no current is delivered to the load capacitence. The current through transistor 322 is then equal to the bias current provided by the current sink 326 and, to a first order approximation, the current in transistor 324 matches that in transistor 322. Should the input voltage drop then transistor 322 will tend to move into its Ohmic region and transistor 320 will start to turn off. Meanwhile the transistor 324 remains in saturation and starts to sink current from the output node to reduce the output voltage at the node 314.

It can be seen that there is a voltage change across transistors 322 and 324 corresponding to the gate source voltage. However the inclusion of the voltage translation circuit incorporating transistor 328 takes account of this and consequently the voltage of the output node 314 is substantially the same as the voltage of the input node 312.

It was noted earlier that the gate of the transistor 320 could be connected to the drain of the transistor 322 but a disadvantage of this is that it makes it more difficult to keep the transistor 322 in saturation under the quiescent operating condition. The inclusion of the level shifting circuit formed by the transistor 330 and the current source 334 provides an additional voltage drop which improves the operation of this buffer amplifier.

This buffer amplifier can be used in substitution of any of the circuits in place of the amplifier 50 with respect to FIGS. 5 and 6.

It is thus possible to provide an improved bias current generation circuit which can be turned on rapidly and which does not necessarily incur much of a footprint on the semiconductor circuit.

1. A bias current generator comprising at least one field effect transistor operating as a current source or sink, a capacitive store for storing a first control voltage, and a first switch for selectively connecting the capacitive store to a gate of the at least one field effect transistor.

2. A bias current generator as claimed in claim 1 further comprising a pre-charge circuit for pre-charging the capacitive store when the capacitive store is not connected to the at least one field effect transistor.

3. A bias current generator as claimed in claim 2 wherein the pre-charge circuit comprises a pre-charge capacitance and a pre-charge switch for selectively connecting the pre-charge capacitor to a pre-charge voltage source.

4. A bias current generator as claimed in claim 3 in which the pre-charge voltage source is a power rail.

5. A bias generator as claimed in claim 3, in which the pre-charge voltage source is a current to voltage converter having a control field effect transistor matched to the at least one field effect transistor operating as a current source or sink and having a gate of the control field effect transistor connected to a drain of the control field effect transistor.

6. A bias generator as claimed in claim 5, in which the gate of the control field effect transistor is connected to the drain of the control field effect transistor by a first impedance, and the gate of the control field effect transistor is connected on a voltage source or to the source of the control field effect transistor by a second impedance, such that the first and second impedances form a potential divider.

7. A bias generator as claimed in claim 1 further comprising a reference limb of a current mirror, comprising a reference field effect transistor in series with a current defining element, and having a gate of the field effect transistor connected to a drain of the field effect transistor, and wherein a potential at the gate of the field effect transistor is supplied to the gate of the at least one field effect transistor operating as a current source or sink.

8. A bias generator as claimed in claim 7, further comprising a buffer arranged to buffer the potential at the gate of the field effect transistor, and to output a buffered voltage to the at least one field effect transistor operating as a current source or current sink.

9. A bias current generator as claimed in claim 8, in which the buffer comprises a pull up stage comprising a first pull up stage field effect transistor and a second pull up stage field effect transistor, each having a drain, a source and a gate, and wherein the drain of the first pull up field effect transistor is connected to a current control device, the source of the first pull up field effect transistor is connected to the potential of the gate of the reference transistor, the drain of the second pull up transistor is connected to a positive voltage supply, the source of the second pull up transistor is connected to an output node of the buffer or to the at least one field effect transistor acting as a current source or a current sink, the gates of the first and second pull up transistors are connected together and directly or indirectly to the drain of the first pull up field effect transistor.

10. A bias current generator as claimed in claim 8, in which the buffer comprises a pull down stage, comprising a first pull down stage field effect transistor and a second pull down stage field effect transistor, each having a drain, a source and a gate, and wherein the drain of the first pull down stage field effect transistor is connected to a current control device, the source of the first pull down transistor is connected to the potential of the gate of the reference field effect transistor, the source of the second pull down field effect transistor is connected to an output node of the buffer or to the gate of the at least one field effect transistor acting as a current source or a current sink, the drain of the second pull down field effect transistor is connected to a ground or a negative voltage rail, and the gates of the first and second pull down transistors are connected together and directly or indirectly to the drain of the first pull down transistor.

11. A bias current generator as claimed in claim 9, in which the buffer further comprises a pull down circuit.

12. A bias current generator as claimed in claim 10, in which the buffer further comprises a pull up circuit.

13. A bias generator comprising a current mirror comprising a first limb for generating a reference voltage as a result of a current flowing in the first limb, and at least one second limb for passing a current as a function of the reference voltage, wherein a buffer is provided between the first and second limbs.

14. A bias generator as claimed in claim 13, further comprising a capacitor arranged to be pre-charged prior to being connected to a control for the at least one second limb, and a switch for selectively connecting the capacitor to the control for the at least one second limb.

15. A bias generator as claimed in claim 14 in which the switch for selectively connecting the capacitor to the control for the at least one second limb is closed so as to initiate conduction in the at least one second limb during a start up period.

16. A bias generator as claimed in claim 1, in which the gates of the at least one field effect transistor operable as a current source or a current sink form a capacitive load, which cooperates with the capacitive store to form a voltage divider.

17. A bias current generator as claimed in claim 1, in which the capacitive store is formed by gate electrodes of one or more field effect transistors.

18. A bias circuit generator as claimed in claim 1, in which there are a plurality of field effect transistors acting as current sources or current sinks, and some of them are grouped such that their gate capacitances form part of the capacitive store.
